(19) United States
(12) Patent Application Publication
(10) Pub. No.: US 2010/0236598 A1
(43) Pub. Date: Sep. 23, 2010

(54) EMBEDDED RFID SOLUTION FOR SOLAR PANELS

(75) Inventors: Jatindra N. Roy, Hyderabad (IN); Vishnuvardhan R. Jammula, Hyderabad (IN); Vamsi M. Athota, Hyderabad (IN); Nazini Furqana, Hyderabad (IN)

Correspondence Address: SCHNECK & SCHNECK, P.O. BOX 2-E, SAN JOSE, CA, 95109-0005, US

(73) Assignee: SOLAR SEMICONDUCTOR PVT. LTD., Hyderabad (IN)

(21) Appl. No.: 12/726,496

(22) Filed: Mar. 18, 2010

Related U.S. Application Data
(60) Provisional application No. 61/161,293, filed on Mar. 18, 2009.

(51) Int. Cl. H01L 31/042; B32B 37/02; H01L 33/18

(52) U.S. Cl. 136/244; 156/60; 257/E31.001

(57) ABSTRACT

A method for producing a solar photovoltaic panel with an embedded RFID, and resultant product, are disclosed. A layup is formed of at least a first lamination layer and a plurality of electrically connected solar photovoltaic cells. At least a second lamination layer is added to the layup, and a lamination process is applied, forming a solar photovoltaic panel. An RFID tag is embedded in the panel before, during or after applying the lamination process. The RFID tag may be embedded between a front layer and a back layer, between sheets of ethylene vinyl acetate, between a backside of the layup and a junction box, or in an adhesive, sealant or polymerizing material. A solar photovoltaic panel with an embedded RFID tag is thereby formed. Instantiation information pertaining to the individual solar photovoltaic panel, including installation location information or test information, and product information are stored in the RFID tag.

### CROSS-REFERENCE TO RELATED APPLICATION

This application claims priority from U.S. provisional application No. 61/161,293, filed Mar. 18, 2009.

### TECHNICAL FIELD

The present invention relates generally to RFID tags and solar photovoltaic panels or modules, more specifically to RFID tags associated with solar photovoltaic panels or modules.

### BACKGROUND

Solar photovoltaic (PV) panels or modules use solar photovoltaic cells in various combinations of parallel or series connections to capture solar energy and convert it electrical power. Other types of solar panels or modules may capture solar energy as heat, for heating water or air. In a residential or commercial installation of solar photovoltaic panels, it may prove advantageous to identify a specific panel or module, so that installation is done correctly according to a specification.

RFID (radio-frequency identification) tags are currently in use to identify various products. The components of an RFID tag and the means by which RFID tags function to respond to an RFID reader are known in the art, and are summarized below.

Radio-frequency identification is an automatic identification method, relying on storing and remotely retrieving data using devices called RFID tags or transponders. The radio frequency (RF) procedure for reading an RFID tag is based upon an LC (inductor and capacitor) resonant circuit adjusted to a defined resonant frequency. RFID tags commonly include inductive resistors made of wound enamelled copper wire with a soldered on capacitor in a plastic housing such as in a hard tag.

FIG. 1 shows an RFID system 100. Such an RFID system 100 has three components: RFID tag 102, RFID reader 104 and host 106.

The RFID reader 104 has an antenna (not shown) as does the RFID tag 102. The respective antennas transmit and receive radio frequency communication between the reader and the tag.

The reader 104 generates an RF signal or wave through the antenna and if the tag 102 is present in the region where the RF is generated, the tag antenna detects and sends the response to the reader. RFID employs radio frequency waves to exchange data between a memory device such as a tag and the reader/controller, which may further communicate with the host, a computer.

The reader 104 can only send and receive data, but the reader does not know what to do with data that is given by the tag 102. Hence a system including a computer helps the reader to communicate with the tag so that the tag can send a response to the reader. The host 106 can send data as given by the manufacturer, which will tell the reader what to do based on the command sent by the host. The reader 104 interfaces between the tag 102 and the host 106 computer, decodes the tag data and passes it on to the host computer. When the reader 104 receives the command from the host 106, based on the command, the reader generates the RF signal. If a tag 102 is present in that region, the tag antenna receives the signal. Based on the command sent by the reader, and if the receiving and responding conditions are met, the tag chip sends the response to the reader.

There are four different kinds of frequencies commonly in use, with differing specifications and typical applications. They are categorized by their radio frequency:

Low frequency (125 KHz-134 KHz): Low-frequency RFID tags are commonly used for animal identification, beer keg tracking, and automobile key-and-lock, anti-theft systems. Pets are often embedded with small chips so that they may be returned to their owners if lost. In the United States, two RFID frequencies are used. One is 125 kHz which is referred as the original standard and 134.5 kHz, the international standard. Using Low-frequency, typically only the tag unique serial number can be read but other data cannot be written into the tag, as it has no further writable memory.

High frequency tags (13.56 MHz): High-frequency RFID tags are used in library book or bookstore tracking, pallet tracking, building access control, airline baggage tracking, and apparel item tracking. High-frequency tags are widely used in identification badges, replacing earlier magnetic stripe cards. These badges need-only be held within a certain distance of the reader to authenticate the holder.

UHF (868 MHz-956 MHz): UHF RFID tags are commercially used in pallet and container tracking, and truck and trailer tracking in shipping yards. UHF tags are not presently typically used globally as there aren't yet any global regulations for their usage. But UHF is very sensitive to metal and water, so that even when a tag is held in a hand the reading range decreases. UHF tags are more expensive than HF and LF tags.

Ultra-high frequency (UHF: 868 MHz-928 MHz) tags are not presently typically used globally as there isn't yet one single global standard. In North America, UHF can be used unlicensed for 908-928 MHz, but restrictions exist for transmission power. In Europe UHF is under consideration for 865.6-867.6 MHz. Its usage is unlicensed for 869.40-869.65 MHz only, but restrictions exist for transmission power. The North-American UHF standard (908-928 MHz) is not accepted in France as it interferes with regional military bandwidths. For China and Japan, there is no regulation for the use of UHF. Each application for UHF in these countries needs a site license, which needs to be applied for at the local authorities, and can be revoked. For Australia and New Zealand, 918-926 MHz is accepted for unlicensed use, but restrictions exist for transmission power.

Microwave (2.45 GHz): Microwave RFID tags are used in long range access control for vehicles.

There are three types of RFID tags, some or all of which may be available in a specified frequency or frequency range:

i) Passive tags.

ii) Active tags.

iii) Semi-passive tags.

Passive RFID tags do not have their own power supply. The minute electrical current induced in the antenna by the incoming radio-frequency scan provides enough power for the tag to send a response. Lack of its own power supply makes the device quite small. The smallest such devices commercially available presently measure 0.4 mm×0.4 mm, and thinner than a sheet of paper. Passive tags have practical read ranges that vary from about 10 mm up to about 5 meters. Passive tags support both 13.56 MHZ and UHF i.e. 865 to 920 MHZ frequencies.

Passive tags are activated by the energy generated by the reader antenna and the reading range is very much less than for active tags. Metal interference may affect the read range of the tags. Passive tags are less expensive than active tags and the passive tags have many applications in consumer goods and other applications.

Active RFID tags, on the other hand, have a power source, longer ranges and larger memories than passive tags, as well as the ability to store additional information sent by the transceiver. At present, the smallest active tags are about the size of a coin. Many active tags have practical ranges of tens of meters, and a battery life of up to several years. Active tags are mostly used for vehicle identification for parking pallets, toll gates or container tracking etc. Active Tags have longer range up to 150 ft and larger memories of 2 KB than passive tags. Semi-passive tags use an internal power source to monitor environmental conditions, but require RF energy transferred from the reader/interrogator similar to passive tags to power a tag response.

### SUMMARY

A method for embedding an RFID tag in a solar photovoltaic panel, and the resultant product, are described. A layup is set up, including at least a first lamination layer. A plurality of electrically connected solar photovoltaic cells is added to the layup. An RFID tag is added to the layup. At least a second lamination layer is added to the layup.

A lamination process is applied to the layup. The method makes forms or produces a solar photovoltaic panel with an embedded RFID tag. The RFID tag may be embedded in the solar photovoltaic panel before, during or after the lamination process is applied.

The RFID tag may be embedded between a back layer and a front layer along with the photovoltaic cells, between a back layer of ethylene vinyl acetate and a front layer of a transparent glass, in a sandwich of strips of ethylene vinyl acetate, or embedded as mounted with adhesive, sealant or polymerizing material and a junction box to a back side of a lamination layer.

Product information is stored in the RFID tag. The product information pertains to the product, of which the individual solar photovoltaic panel is an instantiation.

Further, instantiation information is stored in the RFID tag. The instantiation information pertains to the individual item or instantiation, and includes information about the installation location of the individual solar photovoltaic panel or test information from testing the individual solar photovoltaic panel. The test information may include electrical performance data.

### BRIEF DESCRIPTION OF THE DRAWINGS

FIG. 1 shows an RFID system.

FIG. 2 shows a front view of a solar panel with an embedded RFID tag, in accordance with the present invention.

FIG. 3 shows a back view of a solar panel with an embedded RFID tag in a location differing from that of FIG. 2, in accordance with the present invention.

FIG. 4 shows a Passive HF RFID Tag suitable for embedding in the solar panel of FIG. 2 or 3.

FIG. 5 shows a first example of a laminating process and an ordering of layers suitable for the solar panel of FIG. 2 or 3.

FIG. 6 shows a second example of a laminating process and an ordering of layers suitable for the solar panel of FIG. 2 or 3.

FIG. 7 shows a third example of a laminating process and an ordering of layers suitable for the solar panel of FIG. 2 or 3.

FIG. 8 shows a fifth example of a laminating process and an ordering of layers suitable for the solar panel of FIG. 2 or 3.

FIG. 9 shows a sixth example of a laminating process and an ordering of layers suitable for the solar panel of FIG. 2 or 3.

FIG. 10 shows a seventh example of a laminating process and an ordering of layers suitable for the solar panel of FIG. 2 or 3.

### DETAILED DESCRIPTION

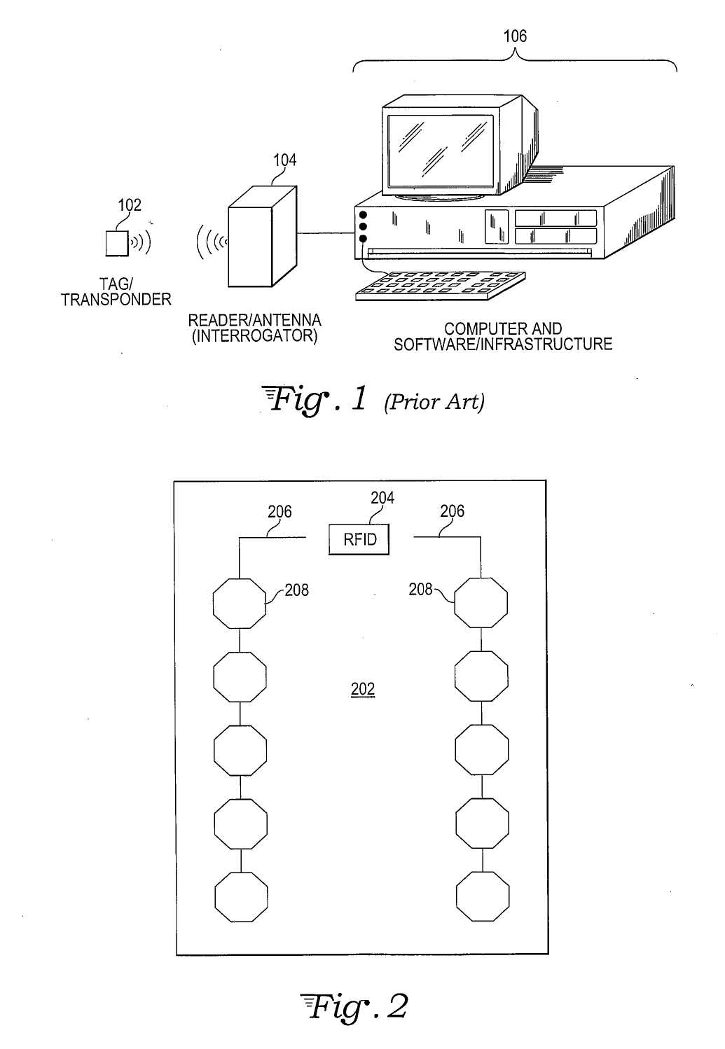

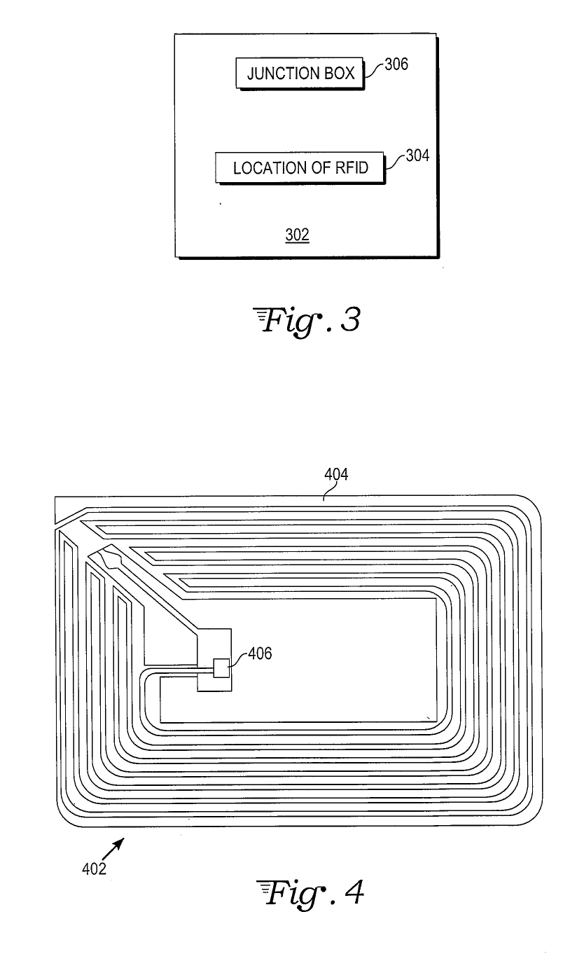

With reference to FIGS. 2 and 3, a method for making an individually identifiable solar photovoltaic panel 202 or 302 with an embedded RFID tag 204 or 304, and the resultant product, are herein disclosed.

Solar panels or modules are the main component for photovoltaic (PV) installation. It is important during and after manufacturing to record certain information regarding each of the panels, including process details and electrical performance test results. This information is used for system design and integration. At present, these data are stored in a media physically separated from the panels and separately supplied to the system integration team. Such separation may give rise to installation delays, errors or reduced system performance, such as when power outputs of individual panels or product types are mismatched in an installation.

The described method and resultant product provide a device, apparatus or system where the desired data can be stored on and accessed from the solar photovoltaic panels themselves. This is done by embedding an RFID in the panel.

Since the solar panel is built to withstand handling, installation, weather and other hard use in an outdoor environment, the RFID tag 204 or 304 embedded in the solar panel 202 or 302 is resistant to accidental or deliberate removal or damage. Thus, the embedded RFID tag provides a means for identifying an individual panel at a building site as well as in case of a theft. A thief, in attempting to remove an embedded RFID tag would likely damage the solar panel, ruining the value of the panel. Because of these factors, the embedded RFID tag is useful as a theft deterrent as well as a theft recovery aid. The RFID tag may be used for tracking inventory, service or repair history, installation verification, end of panel life determination, on-site performance evaluation and more.

Radio Frequency Identification (RFID) is a term used to describe an identification device that can be sensed at a distance, using radio waves. The devices are often referred to as ‘RFID tags’ or ‘Smart Labels’. An RFID tag is an object that can be applied to or incorporated into a product, animal, or person for the purpose of identification and tracking using radio waves. RFID applications typically incorporate a reader within the product or system to add local data-gathering features that enhance the primary functions of the product. An RFID tag is made of a microchip with a tiny antenna. An associated tag reader puts out electromagnetic waves. The tag antenna receives the waves and the tag itself draws power from the field generated by the reader, powering the chip, and then modulates the reader signal, sending a response signal back to the reader where the response signal is converted into digital data.

With reference to FIG. 4, a passive HF RFID tag 402 may be suitable for embedding in the solar panel. The passive HF RFID tag 402 has an antenna 404 and an integrated circuit (IC) 406, with writable memory. In photovoltaic modules, the process details and their electrical performance during and after manufacturing will be recorded by the RFID, which is useful for system design and integration. The embedded RFID provides a convenient way to access such data and minimize human error, as the data stays with the individual panel. It allows adding related system integration data in the same RFID during and after system integration. Some addressable RFID memory space may also be left for recording user information (e.g., customer/owner ID, panel installation date and location, maintenance and repair information or warranty information).

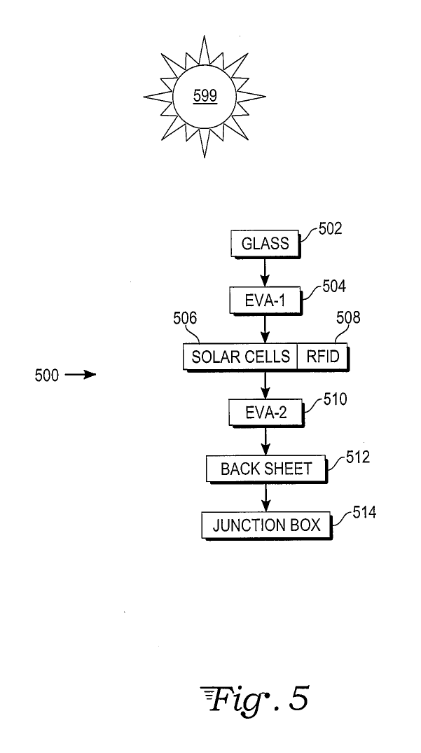

With reference to FIGS. 5-10, nine examples, based upon a standard process flow for solar photovoltaic panels, have been developed for embedding the RFID in the panel. For reference, the standard process flow is described, followed by the developed embedding processes for the RFID. Lamination layers which are above the solar cells when the panel is in use are referred to as front, upper or top layers, for example a front glass layer. Lamination layers which are below the solar cells when the panel is in use are referred to as back, lower or bottom layers. The front side of the finished solar panel faces towards the Sun 599 in use, and the back side of the finished solar panel faces away from the Sun.

For the Standard Process Flow, lamination is one of the important steps. In this flow, a lay-up is done and the cell strings (in which photovoltaic cells may be connected in series) are sandwiched between back sheet-EVA (ethylene vinyl acetate) and EVA-glass (i.e., back sheet as bottom layer, glass as top layer, and EVA/cell string/EVA as intermediate layers). A lamination process is used to laminate this lay-up. After lamination, framing and a junction box are incorporated. Other electrical connections of photovoltaic cells may be used, such as parallel or combinations of series and parallel. The junction box presents and protects the output leads of the solar panel, the output leads being from the electrically connected photovoltaic cells.

With reference to FIG. 5, a first example of a process for embedding an RFID 508 in a solar photovoltaic panel is shown. The RFID 508 is placed along with the photovoltaic cell string (solar cells) 506 between the back sheet plus EVA layers and the EVA plus glass layers. A lamination process that is compatible with the RFID and cell strings, as well as the other lay-up materials, is chosen to meet the required qualification standard. The sequence of layers 500 from the front of the panel to the back of the panel is: glass 502, EVA-1 504, solar cells 506 and RFID 508, EVA-2 510, back sheet 512, junction box 514.

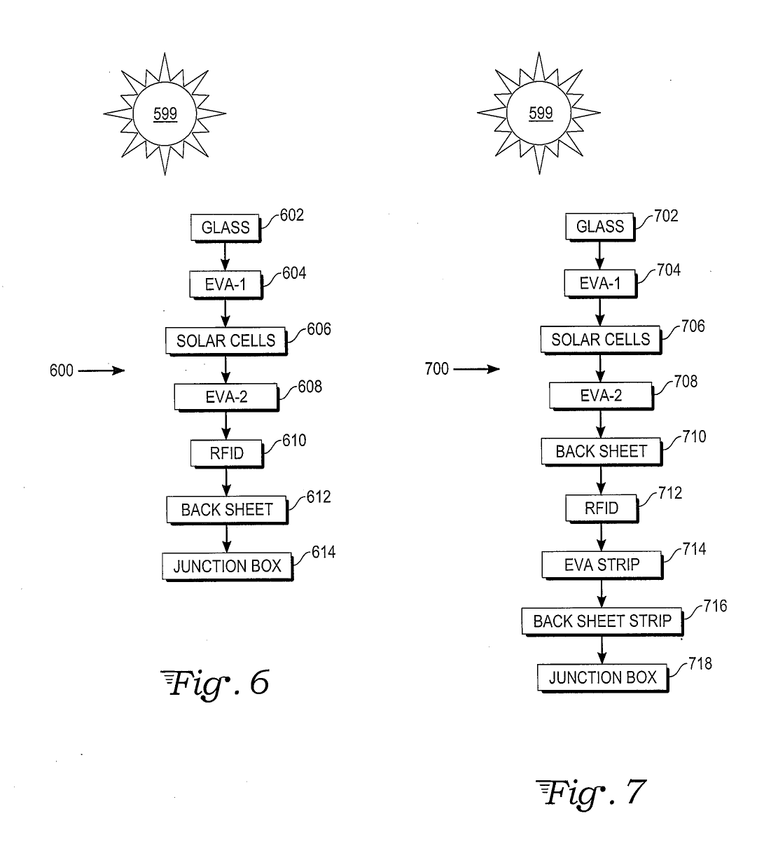

With reference to FIG. 6, a second example of a process for embedding an RFID 610 in a solar photovoltaic panel is shown. The RFID 610 is placed between the back sheet 612 and the EVA that is behind the solar cells 606. A lamination process that is compatible with the RFID and cell strings, as well as the other lay-up materials, is chosen to meet the required qualification standard. The sequence of layers 600 from the front of the panel to the back of the panel is: glass 602, EVA-1 604, solar cells 606, EVA-2 608, RFID 610, back sheet 612, junction box 614. The RFID 610 or 204 may be placed between the EVA-2 608 and the back sheet 612, near the output terminals 206 of the solar cells 208 as shown in FIG. 2.

With reference to FIG. 7, a third example of a process for embedding an RFID 712 in a solar photovoltaic panel is shown. The RFID 712 is placed between the back side of the back sheet 710 and an EVA strip 714. The junction box 718 is mounted to the back side of the back sheet 710. A back sheet strip 716 may cover the EVA strip 714 and the RFID 712, or a data label (not shown) may cover the RFID or the EVA strip and the RFID. A lamination process that is compatible with the RFID and cell strings, as well as the other lay-up materials, is chosen to meet the required qualification standard. The sequence of layers 700 from the front of the panel to the back of the panel is: glass 702, EVA-1 704, solar cells 706, EVA-2 708, back sheet 710, RFID 712, EVA strip 714, back sheet strip 716, junction box 718. The RFID 304 may be placed separated from the junction box 306, as shown in FIG. 3.

In a fourth example of a process for embedding an RFID in a solar photovoltaic panel, the RFID is embedded into the junction box of the photovoltaic module. The RFID may be placed in or covered by a room-temperature vulcanizing (RTV) silicone rubber inside the junction box, with the junction box covering the output leads.

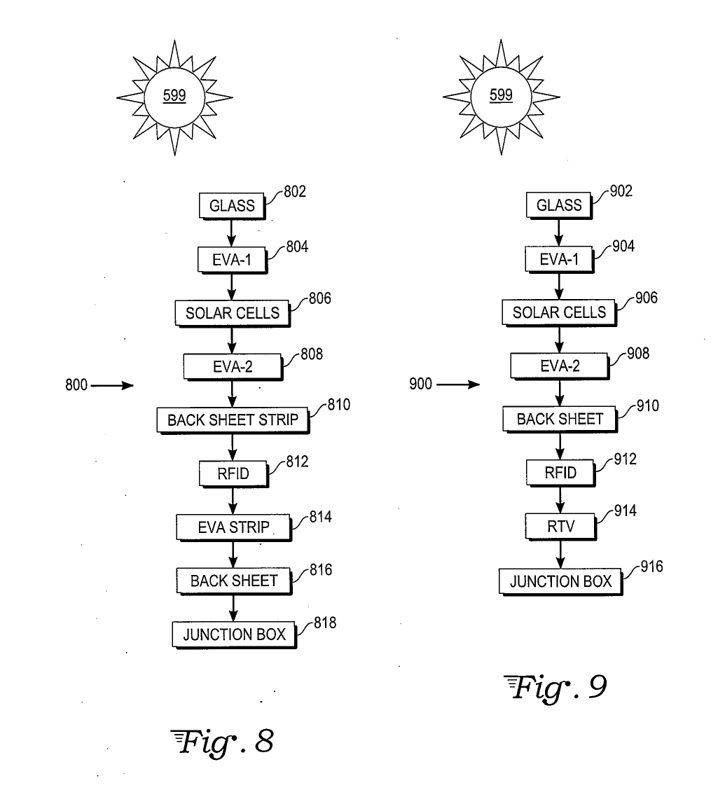

With reference to FIG. 8, a fifth example of a process for embedding an RFID 812 in a solar photovoltaic panel is shown. In this version, the RFID 812 is protected (and is not visible) by putting a strip of EVA 814 beneath and a back sheet strip 810 on top of the RFID 812. This sandwich (EVA strip-RFID-back sheet strip) is then placed on top of the panel back sheet. Again, the lamination process is chosen to ensure compatibility and quality. The sequence of layers 800 from the front of the panel to the back of the panel is: glass 802, EVA-1 804, solar cells 806, EVA-2 808, back sheet strip 810, RFID 812, EVA strip 814, back sheet 816, junction box 818.

With reference to FIG. 9, a sixth example of a process for embedding an RFID 912 in a solar photovoltaic panel is shown. Here, the RFID 912 is embedded after lamination. The RFID 912 is placed on the back sheet 910, covered with RTV silicone rubber 914, and then a junction box 916 is placed on top of it. The process of fitting the junction box 916 to the panel is accordingly modified to accommodate the RFID 912 under the box. The sequence of layers 900 from the front of the panel to the back of the panel is: glass 902, EVA-1 904, solar cells 906, EVA-2 908, back sheet 910, RFID 912, RTV 914, junction box 916.

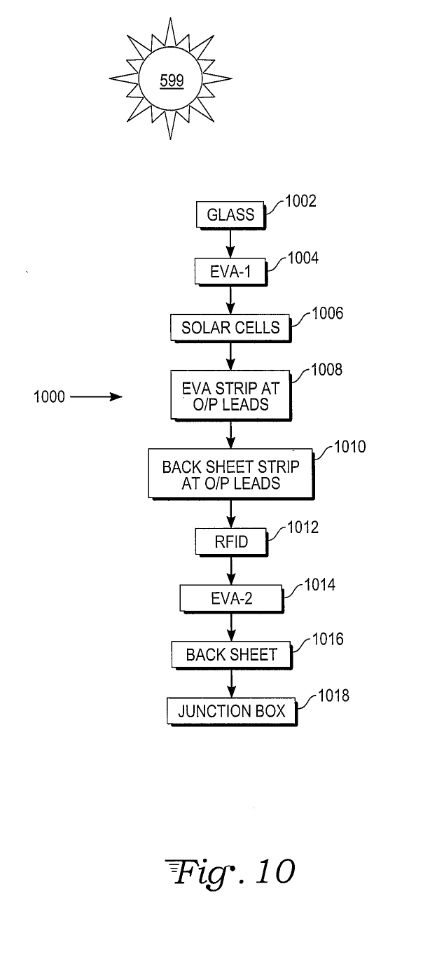

With reference to FIG. 10, a seventh example of a process for embedding an RFID 1012 in a solar photovoltaic panel is shown. The RFID 1012, covered by a back sheet strip 1010 at the output leads and an EVA strip 1008 at the output leads is placed along with the solar cells 1006 between two sheets of EVA. The solar cells may cover the RFID 1012, back sheet strip 1010 and EVA strip 1008, or be adjacent to these, although the output leads from the solar cells 1006 and the RFID 1012 should be arranged so as not to interfere with each other. The junction box 1018 is mounted to the back side of the back sheet 1016. A lamination process that is compatible with the RFID and cell strings, as well as the other lay-up materials, is chosen to meet the required qualification standard. The sequence of layers 1000 from the front of the panel to the back of the panel is: glass 1002, EVA-1 1004, solar cells 1006, EVA strip 1008 at the output leads, back sheet strip 1010 at output leads, RFID 1012, EVA-2 1014, back sheet 1016, junction box 1018. In a variation, the EVA strip 1008 and back sheet strip 1010, as well as the RFID 1012, are placed in a location separate from the output leads.

In an eighth example of a process for embedding an RFID in a solar photovoltaic panel, the RFID is fixed on the back sheet of the module.

In a ninth example of a process for embedding an RFID in a solar photovoltaic panel, the RFID is fixed to the aluminum frame of the photovoltaic module, with the help of an adhesive agent such as foam tape.

The finalized bill of materials is listed below.

Glass, 403×825 mm.

Q Multi-Solar Cells, 156×156 mm.

EVA: FRST F-406B, 408×830 mm.

Back sheet: Protekt HD, 408×830 mm.

Flux: Kester 920 CXF.

Cu interconnectors: Bruker spaleck 2.4×0.13 mm.

Busbars: Bruker spaleck, 5×0.3 mm.

Al (aluminum) Channel 408×830 mm.

RTV: Tonsan 1527.

Junction Box: Tyco, 4-Way.

The following example of a process recipe includes details about a suitable lamination cycle. The lamination cycle finalized was 6+15@138 degrees C. The Platen temperature of the laminator was maintained at 138 degrees C. throughout the lamination cycle. Pump down cycle (Vacuum pump time) and the press cycle were maintained at 6 minutes and 15 minutes respectively.

PV modules were made as per the detail given above. The data was written and then read. All the test requirements have been met as per IEC 61215 standards.

None of the nine above example ways of embedding RFID tags into a PV module has failed the reliability tests. Three out of the nine are considered to be best modes of embedding an RFID tag by considering factors such as the impact of the Al channel on the reading range, protection of the tag and convenient location of the RFID tag so that electrical data can be easily dumped into it:

On the RTV inside the junction box which covers the output leads, per the fourth example.

Between the output leads (in between 2 EVA layers) at top of the module, per the first example and as shown in FIGS. 2 and 5.

Beneath the junction box, in between the back sheet and RTV, per the sixth example and as shown in FIG. 9.

Selection of an RFID tag suitable for embedding in a solar panel may take into account manufacturing and environmental factors as well as whether data storage and reading back is desired, and if so, how much data storage is desired. Having an RFID tag in the module assembly may enable on-module storage of any or all of the following:

A serial number invisible to a camera or an eye

Process information

A date code

Flash test or other test data

Customer ID

Warranty information.

Warranty support, such as repair, service or replacement

Installation location, such as GPS coordinates

Security information, such as to aid in recovering a stolen module

A data encryption format

Hidden or tamperproof information

Locked data

Inventory management information

Module class

Comments

Automation information

Information stored in the RFID tag embedded in the solar photovoltaic panel may be used for purposes associated with the type of information or for other purposes.

With reference back to FIG. 3, a passive HF RFID tag was found suitable for embedding in the solar panel. The passive HF RFID tag consists of a chip with the antenna, and the tag has some memory in which data can be written and read. The amount of memory of the tags varies as per the manufacturer specification. Other suitable RFID tags may be identified or developed by a person skilled in the art.

One type of passive HF RFID tag suitable for embedding in a solar panel is the LRP-S series RFID tags from NXP™. These tags have the following characteristics, as reported by the manufacturer:

Dimensions of RFID Tag: 4.6×1.2 cm.

Operating frequency: 13.56 MHz.

Operating temperature: 60 degrees C.

Storing Temperature: 80 degrees C.

Reading range: 15 cm.

Can read/write up to 112 bytes.

Can read and write data multiple times.

Experiments to further determine suitability of the RFID tag were performed. The tag has a practical reading range of 14.5 cm. The tag can be operated up to 100 degrees C.

In one experiment, in which the tag was exposed to a temperature of 140 degrees C. during lamination, the tag was able to have data written to it and read from it after the lamination process. An observed conclusion is that the tag can be stored up to 140 degrees C., at least for short periods of time such as during the lamination process.

Other experiments show the tag can be stored at up to 85% RH (relative humidity).

To determine how metal interference will affect the reading range of the tag, an experiment was conducted. Results of the experiment show that the reading range from the RFID tag is affected by the distance between the RFID tag and an aluminum channel, as tabulated below.

Distance between aluminum channel and RFID tag 0.1 cm results in a reading range from the RFID tag of 0 cm, and the tag was not detected.

Distance between aluminum channel and RFID tag 0.2 cm results in a reading range from the RFID tag of 1.7 cm, and the tag was detected.

Distance between aluminum channel and RFID tag 0.3 cm results in a reading range from the RFID tag of 3.6 cm, and the tag was detected.

Distance between aluminum channel and RFID tag 0.4 cm results in a reading range from the RFID tag of 6.0 cm, and the tag was detected.

Distance between aluminum channel and RFID tag 0.5 cm results in a reading range from the RFID tag of 7.5 cm, and the tag was detected.

Distance between aluminum channel and RFID tag 0.6 cm results in a reading range from the RFID tag of 9.0 cm, and the tag was detected.

Distance between aluminum channel and RFID tag 0.7 cm results in a reading range from the RFID tag of 10.2 cm, and the tag was detected.

Distance between aluminum channel and RFID tag 0.8 cm results in a reading range from the RFID tag of 10.6 cm, and the tag was detected.

Distance between aluminum channel and RFID tag 0.9 cm results in a reading range from the RFID tag of 11.7 cm, and the tag was detected.

Distance between aluminum channel and RFID tag 1.0 cm results in a reading range from the RFID tag of 12.0 cm, and the tag was detected.

From the above experiment, the observations are that as distance is increased between the RFID tag and the aluminum channel, the reading range increases, and that the maximum reading range of this tag is 12 cm.

Examples of data that may be written into an RFID tag suitable for embedding in the solar photovoltaic panel are given below. Product information, such as a model name or number, a manufacturer name, a general power rating for the type of solar panel or other information relating to the product may be written to the RFID tag. Instantiation information specific to an individual item, such as test data from testing the individual solar panel, or a location where the individual panel was or will be installed, may be written to the RFID tag. A serial number and any data relating to testing of an individual panel are specific to that instance of the product. Data may be written to the RFID tag before or after the tag is embedded in the solar panel, and may be written by the manufacturer, distributor, a user or other personnel, at a factory, warehouse, point of sale, installation location, repair facility or elsewhere. The following is an example of data written to an RFID tag embedded in a specific, individual panel:

Module number (may combine model number and serial number): S15S1120090246596

Open circuit voltage: Voc=36.31 V

Short-circuit current: Isc=8.61 A

Voltage at maximum power point: Vmp=28.55 v

Current at maximum power point: Imp=7.85 A

Fill Factor (defined as Vmp×Imp/Voc×Isc): FF=71.70%

Maximum Power (defined as Vmp×Imp): Pmax=224.07 W

Total number of bytes utilised is 81, leaving 31 bytes, for an RFID tag with 112 bytes.

Online Process data entered into the RFID tags are:

Recipe number: 2 bytes. The Recipe number may refer to a table of recipes with details of tabbers and stringers including chuck temperatures, etc.

Laminator number: 2 bytes.

Lamination cycle: 11 bytes (Ex: 6+12@140 degrees C.).

Make of the main materials such as glass, EVA, and Junction box

If numbers are fixed for each material: 6 bytes.

To feed online process data into an RFID tag, 32 bytes are required excluding commas or semicolons and 37 bytes including commas or semicolons. In this example, 31 bytes remain.

Example of data written into the RFID tag: R=01; L=01; LC=4+12@140; G=01; E=01; JB=01

An RFID tag embedded in a solar photovoltaic panel by the above-described method is durable and difficult to remove without damaging the panel. Some placements of the RFID tag are not visible to a user and provide non-visible identification means. Thus, the method and the resultant product provide a means to identify an individual panel, a means to keep information about the product and the individual panel always with the panel, and resistance to theft or accidental damage to the identification means during handling, servicing or use.

What is claimed is:

1. A method for manufacturing an identifiable solar photovoltaic panel, the method comprising:
forming a layup of at least a first lamination layer, a plurality of electrically connected solar photovoltaic cells and at least a second lamination layer;
applying a lamination process to the layup thereby forming a solar photovoltaic panel;
embedding an RFID tag in the solar photovoltaic panel before, during or after applying the lamination-process thereby making a solar photovoltaic panel with an embedded RFID tag;
storing product identification information in the RFID tag pertaining to a product of which the solar photovoltaic panel is an individual item; and
storing instantiation information in the RFID tag pertaining to the individual item, the instantiation information including installation location information or test information.

2. The method of claim 1 wherein:
the at least a first lamination layer includes the RFID tag and a back layer of ethylene vinyl acetate;
the at least a second lamination layer includes a front layer of a transparent glass; and
the solar photovoltaic cells and the RFID tag are placed between the back layer and the front layer before or during the lamination process.

3. The method of claim 1 further comprising:
sandwiching the RFID tag between a first strip of ethylene vinyl acetate and a second strip of ethylene vinyl acetate thereby forming a sandwiched RFID tag; and
placing the sandwiched RFID tag on the at least a first lamination layer.

4. The method of claim 1 wherein embedding an RFID tag in the solar photovoltaic panel includes:
placing the RFID tag on a backside of the solar photovoltaic panel;
covering the RFID tag with an adhesive, a sealant or a polymerizing material; and
placing a junction box on the RFID tag.

5. The method of claim 1 wherein the product identification information includes: a product name, a product number, a warranty information or a module class.

6. The method of claim 1 wherein the instantiation information includes: a serial number, a process information, a date code, test data, a customer ID, GPS coordinates or other installation location information, security information, data encryption information, an installation date, maintenance information, repair information or comments.

7. A method for manufacturing an individually identifiable solar photovoltaic panel, the method comprising:
setting up a layup of at least a first lamination layer;
adding a plurality of electrically connected solar photovoltaic cells to the layup;
adding an RFID tag to the layup;
adding at least a second lamination layer to the layup;
applying a lamination process to the layup thereby forming a solar photovoltaic panel with an embedded RFID tag as an instantiation of a solar photovoltaic panel product;
storing product identification information in the RFID tag pertaining to the product of which the solar photovoltaic panel is the instantiation; and
storing instantiation information in the RFID tag pertaining to the instantiation of the solar photovoltaic panel, the instantiation information including installation location information or test information.

8. The method of claim 7 wherein:
the solar photovoltaic panel includes a back layer of ethylene vinyl acetate and a front layer of a transparent glass; and
the solar photovoltaic cells and the RFID tag are added between the back layer and the front layer.

9. The method of claim 7 further comprising:
sandwiching the RFID tag between a first strip of ethylene vinyl acetate and a second strip of ethylene vinyl acetate thereby forming a sandwiched RFID tag; and
placing the sandwiched RFID tag on the at least a first lamination layer or between the first and second lamination layers.

10. The method of claim 7 wherein adding an RFID tag to the layup includes adding the RFID tag, a room-temperature vulcanizing silicone rubber and a junction box to a backside of the layup before, during or after applying the lamination process.

11. The method of claim 7 wherein the product identification information includes a product name or a product number.

12. The method of claim 7 wherein the instantiation information includes a serial number or a customer ID.

13. The method of claim 7 wherein the instantiation information includes electrical performance data derived from testing the instantiation of the solar photovoltaic panel.

14. The method of claim 7 wherein the instantiation information includes information written into the RFID tag after the solar photovoltaic panel is purchased by a user.

15. The method of claim 7 wherein the instantiation information includes GPS coordinates or other installation location information.

16. The method of claim 7 wherein the instantiation information includes user information.

17. A solar photovoltaic panel comprising:
a first lamination layer;
a plurality of electrically connected solar photovoltaic cells;
a second lamination layer;
an RFID tag embedded in a laminated assembly including the first lamination layer, the plurality of electrically connected solar photovoltaic cells and the second lamination layer;
the RFID tag containing product information relating to the product of which an individual solar photovoltaic panel is an instance; and
the RFID tag further containing information specific to the individual solar photovoltaic panel.

18. The solar photovoltaic panel of claim 17 wherein:
the first lamination layer includes a back layer of ethylene vinyl acetate;
the second lamination layer includes a front layer of a transparent glass; and
the RFID tag is between the back layer and the front layer.

19. The solar photovoltaic panel of claim 17 wherein:
the first lamination layer is a back layer of ethylene vinyl acetate;
the second lamination layer is a front layer of a transparent glass; and
the RFID tag is in a sandwich between a first strip of ethylene vinyl acetate and a second strip of ethylene vinyl acetate, and the sandwich is between the back layer and the front layer.

20. The solar photovoltaic panel of claim 17 wherein the RFID tag, a polymerizing material and a junction box are mounted to a backside of the first lamination layer as part of the laminated assembly, thereby embedding the RFID tag in the laminated assembly.

21. The solar photovoltaic panel of claim 17 wherein the information specific to the individual solar photovoltaic panel includes electrical performance data.

22. The solar photovoltaic panel of claim 17 wherein the information specific to the individual solar photovoltaic panel includes GPS coordinates or other installation location information.

23. The solar photovoltaic panel of claim 17 wherein the information specific to the individual solar photovoltaic panel includes user information.
